(19) United States
(12) Patent Application Publication
(10) Pub. No.: US 2021/0191259 A1
(43) Pub. Date: Jun. 24, 2021

(54) COLORED PHOTOSENSITIVE RESIN COMPOSITION AND BLACK MATRIX PREPARED THEREFROM

(71) Applicant: ROHM AND HAAS ELECTRONIC MATERIALS KOREA LTD., Chungcheongnam-do (KR)

(72) Inventors: Hyung Tak Jeon, Gyeonggi-do (KR); Kyu Cheol Lee, Gyeonggi-do (KR); Seung-Keun Kim, Gyeonggi-do (KR); Seung-Kyu Song, Gyeonggi-do (KR)

(21) Appl. No.: 17/119,708

(22) Filed: Dec. 11, 2020

(30) Foreign Application Priority Data
Dec. 24, 2019 (KR) 10-2019-0173994
Oct. 26, 2020 (KR) 10-2020-0139634

(51) Int. Cl. G03F 7/00; C08F 220/14; C08F 212/08; G03F 7/033; G03F 7/004

(52) U.S. Cl. CPC G03F 7/0007; C08F 220/14; C08F 212/08; G02B 5/003; G03F 7/0045; G03F 7/0042; G03F 7/033

(57) ABSTRACT

The colored photosensitive resin composition of the present invention comprises a multifunctional thiol compound and/or a compound containing a double bond and a hydroxyl group, whereby it can sufficiently form a cured film even at low temperatures. In addition, the photosensitive resin composition of the present invention has a fast development speed and excellent resolution and chemical resistance.

### TECHNICAL FIELD

The present invention relates to a colored photosensitive resin composition capable of forming a cured film having excellent developability and resolution even at low temperatures, and a black matrix prepared therefrom.

### BACKGROUND ART

Colored photosensitive resin compositions are widely used in LCDs, OLEDs, and quantum dot (QD)-based display devices.

An LCD is composed of an upper substrate, a lower substrate, and liquid crystals interposed between the substrates. If necessary, a touch screen panel (TSP) or the like may be connected to the upper substrate. In general, a TSP is fabricated after the assembly step in which a color filter and a thin film transistor (TFT) are combined. In order to minimize the impact on the color filter, which has already been fabricated, a composition must be cured at a low temperature to prepare a cured film. However, there is a problem that the composition is not sufficiently crosslinked when cured at a low temperature, failing to form a cured film, or the strength thereof is not sufficient. Thus, there is a need for a composition capable of being cured at low temperatures. In addition, OLEDs and quantum dot (QD)-based display devices require a composition suitable for curing at low temperatures since they are fabricated at low temperatures.

Meanwhile, a technique for preparing a cured film by curing a composition comprising an acrylate-based resin as a binder at a low temperature has been known in the relevant art (see Korean Laid-open Patent Publication No. 2010-0029479). But it is not sufficient to satisfy the chemical resistance.

Conventional colored compositions curable at low temperatures use an excessive amount of a thermally curing agent such as an epoxy compound or an additive for lowering the reaction energy in order to increase the degree of curing at low temperatures. However, these substances have a problem in terms of storage stability, causing problems such as peeling, pattern tearing, and lack of resolution in the process of preparing a cured film.

### DETAILED DESCRIPTION OF THE INVENTION

### Technical Problem

Accordingly, the present invention aims to provide a colored photosensitive resin composition capable of being sufficiently crosslinked and cured at low temperatures and having excellent chemical resistance, developability, and resolution of the pattern, and a black matrix prepared therefrom.

### Solution to the Problem

In order to achieve the above object, the present invention provides a photosensitive resin composition, which comprises (A) a copolymer; (B) a photopolymerizable compound; (C) a photopolymerization initiator; (D) a colorant; and (E) a multifunctional thiol compound.

In order to achieve another object, the present invention provides a black matrix prepared from the photosensitive resin composition.

### Advantageous Effects of the Invention

The colored photosensitive resin composition of the present invention comprises a multifunctional thiol compound and/or a compound containing a double bond and a hydroxyl group, whereby it can sufficiently form a cured film even at low temperatures. In addition, the photosensitive resin composition of the present invention has a fast development speed and excellent resolution and chemical resistance.

### BRIEF DESCRIPTION OF THE DRAWINGS

FIG. 1 is a photograph of the surface of cured films prepared from the compositions of the Examples taken with an optical microscope.

FIG. 2 is a photograph of the surface of cured films prepared from the compositions of the Comparative Examples with an optical microscope.

### BEST MODE FOR CARRYING OUT THE INVENTION

The present invention is not limited to those described below. Rather, it can be modified into various forms as long as the gist of the invention is not altered.

Throughout the present specification, when a part is referred to as “comprising” an element, it is understood that other elements may be comprised, rather than other elements are excluded, unless specifically stated otherwise. In addition, all numbers and expressions relating to quantities of components, reaction conditions, and the like used herein are to be understood as being modified by the term “about” unless specifically stated otherwise.

The present invention provides a photosensitive resin composition, which comprises (A) a copolymer; (B) a photopolymerizable compound; (C) a photopolymerization initiator; (D) a colorant; and (E) a multifunctional thiol compound.

The composition may optionally further comprise (F) a compound containing two or more double bonds and two or more hydroxyl groups, (G) a photobase generator, (H) an epoxy compound, (I) an adhesion aid, (J) a surfactant, and/or (K) a solvent.

As used herein, the term “(meth)acryl” refers to “acryl” and/or “methacryl,” and the term “(meth)acrylate” refers to “acrylate” and/or “methacrylate.”

The weight average molecular weight (g/mole or Da) of each component as described below is measured by gel permeation chromatography (GPC, eluent: tetrahydrofuran) referenced to a polystyrene standard.

### (A) Copolymer

The copolymer (A) may comprise at least one selected from the group consisting of (a1) a structural unit derived from an unsaturated monomer containing an acid group; (a2) a structural unit derived from an unsaturated monomer containing an alicyclic epoxy group; (a3) a structural unit derived from an unsaturated monomer containing an acyclic epoxy group; and (a4) a structural unit derived from an unsaturated monomer different from (a1) to (a3).

Specifically, the copolymer (A) may comprise two or more, three or more, or four or more selected from the group consisting of the structural units (a1) to (a4).

More specifically, the copolymer (A) may comprise the structural unit (a4) and may further comprise (a1), (a2), and/or (a3).

(a1) Structural Unit Derived From an Unsaturated Monomer Containing an Acid Group

The copolymer (A) may comprise (a1) a structural unit derived from an unsaturated monomer containing an acid group.

The structural unit (a1) in the present invention may be derived from an unsaturated monomer containing an acid group.

The unsaturated monomer containing an acid group may be an ethylenically unsaturated compound containing an acid group, specifically a succinate-based acrylate compound.

Examples of the succinate-based acrylate compound include at least one selected from the group consisting of mono-2-acryloyloxyethyl succinate, mono-2-methacryloyloxyethyl succinate, 4-(2-(acryloyloxy)ethoxy)-4-oxobutanoic acid, 4-(3-(methacryloyloxy)propoxy)-4-oxobutanoic acid, and 4-((5-(methacryloyloxy)pentypoxy)-4-oxobutanoic acid.

TABLE 1

| | |
|---|---|
| Mono-2-acryloyloxyethyl succinate | 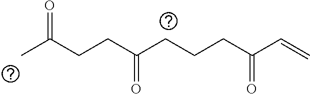 |
| Mono-2-methacryloyloxyethyl succinate | 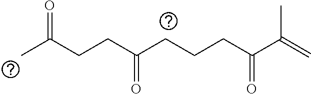 |
| 4-(2-(acryloyloxy)ethoxy)-4-oxobutanoic acid | 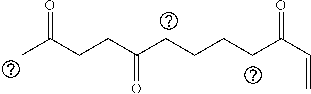 |
| 4-(3-(methacryloyloxy)propoxy)-4-oxobutanoic acid | 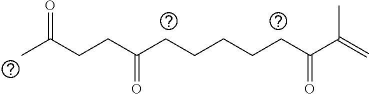 [SMILES: C=C(C)C(=O)CCCCCC(=O)CCC(C)=O] |
| 4-((5-(methacryloyloxy)pentyl)oxy)-4- oxobutanoic acid | 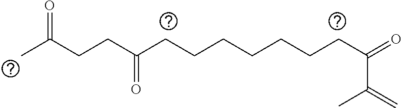 [SMILES: C=C(C)C(=O)CCCCCCCC(=O)CCC(C)=O] |

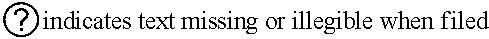

The amount of the structural unit (a1) may be 5% by mole to 50% by mole, 5 to 40% by mole, 5 to 30% by mole, 5 to 20% by mole, or 5 to 15% by mole, based on the total number of moles of the structural units constituting the copolymer (A). Within the above range, the solubility of the composition is improved so that the pattern is not detached during development, and excellent pattern straightness and resolution can be obtained.

### (a2) Structural Unit Derived From an Unsaturated Monomer Containing an Alicyclic Epoxy-Group

The copolymer (A) may comprise (a2) a structural unit derived from an unsaturated monomer containing an alicyclic epoxy group.

The structural unit (a2) in the present invention may be derived from an unsaturated monomer containing an alicyclic epoxy group.

The unsaturated monomer (a2) containing an alicyclic epoxy group may be 2,4-methyl acrylate, 3,4-epoxycyclohexylmethyl acrylate, or 3,4-epoxycyclohexylmethyl methacrylate.

The amount of the structural unit (a2) may be 5% by mole to 50% by mole, 5 to 40% by mole, 5 to 30% by mole, 5 to 20% by mole, 10 to 50% by mole, 10 to 40% by mole, 10 to 30% by mole, 10 to 20% by mole, or 10 to 15% by mole, based on the total number of moles of the structural units constituting the copolymer (A). Within the above range, the storage stability of the composition is maintained, and the film retention rate is enhanced.

### (a3) Structural Unit Derived From an Unsaturated Monomer Containing an Acyclic Epoxy Group

The copolymer (A) may comprise (a3) a structural unit derived from an unsaturated monomer containing an acyclic epoxy group.

The structural unit (a3) in the present invention may be derived from an unsaturated monomer containing an acyclic epoxy group.

The unsaturated monomer containing an acyclic epoxy group may be glycidyl acrylate, glycidyl methacrylate, or 4-hydroxybutyl acrylate glycidyl ether.

The amount of the structural unit (a3) may be 5% by mole to 50% by mole, 5 to 40% by mole, 5 to 30% by mole, 5 to 20% by mole, or 5 to 15% by mole, based on the total number of moles of the structural units constituting the copolymer (A). Within the above range, the storage stability of the composition is maintained, and the film retention rate is enhanced.

If the copolymer (A) comprises the structural units (a2) and (a3) at the same time, the total amount of the structural units (a2) and (a3) may be 5 to 60% by mole, 10 to 60% by mole, 10 to 50% by mole, or 10 to 45% by mole, based on the total number of moles of the structural units of the copolymer (A). In addition, the molar ratio of the structural units (a2) and (a3) may be 50 to 99:50 to 1, 50 to 90:50 to 10, 50 to 85:50 to 15, 50 to 80:50 to 20, or 50 to 75:50 to 25. Within the above range, it is possible to achieve excellent stability over time at room temperature, thermal resistance, and chemical resistance, and the pattern formation is enhanced.

### (a4) Structural Unit Derived From an Unsaturated Monomer Different From (a1) to (a3)

The copolymer (A) may comprise (a4) a structural unit derived from an unsaturated monomer different from (a1) to (a3). In such event, the structural unit (a4) may be derived from one or more, two or more, or three or more unsaturated monomers.

The copolymer (A) in the present invention may further comprise (a4) a structural unit different from (a1) to (a3). The structural unit (a4) may be derived from an ethylenically unsaturated compound different from the structural units described above.

Specifically, the structural unit (a4) may be derived from an ethylenically unsaturated carboxylic acid, an ethylenically unsaturated carboxylic anhydride, or a combination thereof. Examples thereof include an unsaturated monocarboxylic acid such as (meth)acrylic acid, crotonic acid, α-chloroacrylic acid, and cinnamic acid; an unsaturated dicarboxylic acid and an anhydride thereof such as maleic acid, maleic anhydride, fumaric acid, itaconic acid, itaconic anhydride, citraconic acid, citraconic anhydride, and mesaconic acid; and an unsaturated polycarboxylic acid of trivalence or more and an anhydride thereof.

In addition, it may be at least one selected from the group consisting of an ethylenically unsaturated compound having an aromatic ring such as phenyl (meth)acrylate, benzyl (meth)acrylate, 2-phenoxyethyl (meth)acrylate, phenoxy diethylene glycol (meth)acrylate, p-nonylphenoxy polyethylene glycol (meth)acrylate, p-nonylphenoxy polypropylene glycol (meth)acrylate tribromophenyl (meth)acrylate, styrene, methylstyrene, dimethylstyrene, trimethylstyrene ethylstyrene, diethylstyrene, triethylstyrene, propyl styrene, butylstyrene, hexylstyrene, heptyistyrene, octylstyrene, fluorostyrene, chlorostyrene, bromostyrene, iodostyrene, methoxystyrene, ethoxystyrene, propoxystyrene, p-hydroxy-α-methylstyrene, acetylstyrene, vinyl toluene, divinylbenzene, vinylphenol, o-vinylbenzyl methyl ether, m-vinylbenzyl methyl ether, and p-vinylbenzyl methyl ether; an unsaturated carboxylic acid ester such as methyl (meth)acrylate, ethyl (meth)acrylate, butyl (meth)acrylate, dimethylaminoethyl (meth)acrylate, isobutyl (meth)acrylate, t-butyl (meth)acrylate, cyclohexyl (meth)acrylate, ethylhexyl (meth)acrylate, tetrahydrofurfuryl (meth)acrylate, hydroxyethyl (meth)acrylate, 2-hydroxypropyl (meth)acrylate, 2-hydroxy-3-chloropropyl (meth)acrylate, 4-hydroxybutyl (meth)acrylate, glycerol (meth)acrylate, methyl α-hydroxymethylacrylate, ethyl α-hydroxymethylacrylate, propyl α-hydroxymethylacrylate, butyl α-hydroxymethylacrylate, 2-methoxyethyl (meth)acrylate, 3-methoxybutyl (meth)acrylate, ethoxy diethylene glycol (meth)acrylate, methoxy triethylene glycol (meth)acrylate, methoxy tripropylene glycol (meth)acrylate, polyethylene glycol) methyl ether (meth)acrylate, tetrafluoropropyl (meth)acrylate, 1,1,1,3,3,3-hexafluoroisopropyl (meth)acrylate, octafluoropentyl (meth)acrylate, heptadecafluorodecyl (meth)acrylate, isobornyl (meth)acrylate, dicyclopentanyl (meth)acrylate, dicyclopentenyl (meth)acrylate, dicyclopentanyloxyethyl (meth)acrylate, and dicyclopentenyloxyethyl (meth)acrylate; an N-vinyl tertiary amine containing an N-vinyl group such as N-vinyl pyrrolidone, N-vinyl carbazole, and N-vinyl morpholine; an unsaturated ether such as vinyl methyl ether and vinyl ethyl ether and an unsaturated imide such as N-phenylmaleimide, N-(4-chlorophenyl)maleimide, N-(4-hydroxyphenyl)maleimide, and N-cyclohexylmaleimide.

The amount of the structural unit (a4) may be 50 to 99% by mole, 50 to 90% by mole, 55 to 85% by mole, or 60 to 80% by mole, based on the total number of moles of the structural units of the copolymer (A). Within the above range, it is possible to control the reactivity of the copolymer (A) and to increase the solubility thereof, so that the amiability of the photosensitive resin composition is remarkably enhanced.

The copolymer (A) used in the present invention may have a weight average molecular weight of 10,000 Da or more, or less than 10,000 Da. In such event, the copolymer (A) having a weight average molecular weight of less than 10,000 Da cannot be used alone. It must be used in combination with a copolymer of 10,000 Da or more. Specifically, the copolymer (A) used in the present invention may have a weight average molecular weight of 10,000 Da or more. 15,000 Da or more, 10,000 to 50,000 Da, 12,000 to 45,000 Da, or 15,000 to 40,000 Da. In addition, the copolymer (A) used in the present invention may have a weight average molecular weight of 5,000 to less than 10,000 Da, 5,000 to 9,000 Da, 5,000 to 8,000 Da, or 5,000 to 7,000 Da. If it has a weight average molecular weight within the above range, the adhesion to a substrate is excellent, the physical and chemical properties are favorable, and the viscosity is proper.

The copolymer (A) used in the present invention may comprise at least one selected from the group consisting of the structural units (a1) to (a4) as described above. For example, the copolymer (A) may comprise a combination of the structural units (a1) to (a4), a combination of (a2) to (a4), a combination of (a2) and (a3), a combination of (a2) and (a4), and a combination of (a3) and (a4).

The copolymer (A) used in the present invention may be synthesized by copolymerization known in the art. The amount of the copolymer (A) may range from 10 to 50% by weight, 10 to 40% by weight, 10 to 35% by weight, 15 to 40% by weight, 15 to 35% by weight, or 20 to 35% by weight, based on the total weight of the photosensitive resin composition excluding the balanced amount of solvents. Within the above range, a pattern profile after development may be favorable, and such properties as film retention rate and chemical resistance may be enhanced.

### (B) Photopolymerizable Compound

The photopolymerizable compound (or monomer) employed in the present invention is a compound that is polymerizable by the action of a photopolymerization initiator. It may include a monofunctional or multifunctional ester compound of acrylic acid or methacrylic acid having at least one ethylenically unsaturated group. It may preferably be a multifunctional compound having at least two functional groups from the viewpoint of chemical resistance.

The polymerizable compound may be at least one selected from the group consisting of ethylene glycol di(meth)acrylate, propylene glycol di(meth)acrylate diethylene glycol di(meth)acrylate triethylene glycol di(meth)acrylate 1,6-hexanediol di(meth)acrylate, polyethylene glycol di(meth)acrylate, polypropylene glycol di(meth)acrylate, glycerin tri(meth)acrylate, trimethyolpropane tri(meth)acrylate, pentaerythritol tri(meth)acrylate, a monoester of pentaerythritol tri(meth)acrylate and succinic acid, pentaerythritol tetra(meth)acrylate, dipentaerythritol penta(meth)acrylate, dipentaerythritol hexa(meth)acrylate, a monoester of dipentaerythritol penta(meth)acrylate and succinic acid, caprolactone modified dipentaerythritol hexa(meth)acrylate, pentaerythritol triacrylate-hexamethylene di isocyanate (a reaction product of pentaerythritol triacrylate and hexamethylene diisocyanate), tripentaerythritol hepta(meth)acrylate, tripentaerythritol octa(meth)acrylate, bisphenol A epoxyacrylate, and ethylene glycol monomethyl ether acrylate, but it is not limited thereto.

Examples of the photopolymerizable compound commercially available may include a monofunctional (meth)acrylate such as Aronix M-101, M-111, and M-114 manufactured by Toagosei Co., Ltd., KAYARAD TC-110S and TC-120S manufactured by Nippon Kayaku Co., Ltd., and V-158 and V-2311 manufactured by Osaka Yuki Kagaku Kogyo Co., Ltd.; a bifunctional (meth)acrylate such as Aronix M-210, M-240, and M-6200 manufactured by Toagosei Co., Ltd., KAYARAD HDDA, HX-220, and R-604 manufactured by Nippon Kayaku Co., Ltd., and V-260, V-312, and V-335 HP manufactured by Osaka Yuki Kagaku Kogyo Co., Ltd.; and a tri- and higher functional (meth)acrylate such as Aronix M-309, M-400, M-403, M-405, M-450, M-7100, M-8030, M-8060, and TO-1382 manufactured by Toagosei Co., Ltd., KAYARAD TMPTA, DPHA, DPHA-40H, DPCA-20, DPCA-30, DPCA-60, and DPCA-120 manufactured by Nippon Kayaku Co., Ltd., and V-295, V-300, V-360, V-GPT, V-3PA, and V-400 manufactured by Osaka Yuki Kagaku Kogyo Co., Ltd,

The photopolymerizable compounds may be used alone or in combination of two or more thereof. The photopolymerizable compound may be employed in an amount of 10 to 100 parts by weight, 10 to 90 parts by weight, 10 to 80 parts by weight, 20 to 90 parts by weight, 20 to 80 parts by weight. 25 to 80 parts by weight, or 25 to 60 parts by weight, based on 100 parts by weight of the copolymer (A) (based on the solids content). Within the above range, a pattern development is favorable, and excellent chemical resistance and elastic restoring force may be achieved.

### (C) Photopolymerization Initiator

The photopolymerization initiator employed in the present invention may be any known photopolymerization initiator.

The photopolymerization initiator may be selected from the group consisting of an acetophenone-based compound, a non-imidazole-based compound, a triazine-based compound, an onium salt-based compound, a benzoin-based compound, a benzophenone-based compound, a polynuclear quinone-based compound, a thioxanthone-based compound, a diazo-based compound, an imidesulfonate-based compound, an oxime-based compound, a carbazole-based compound, a sulfonium borate-based compound, a ketone-based compound, and a mixture thereof. Specifically, the photopolymerization initiator may be at least one selected from the group consisting of an oxime-based compound, a triazine-based compound, or a ketone-based compound. More specifically, the photopolymerization initiator may be a combination of an oxime-based compound and a triazine-based compound or a combination of an oxime-based compound, a triazine-based compound, and a ketone-based compound.

Particular examples of the photopolymerization initiator may include 2,2′-azobis(2,4-dimethylvaleronitrile), 2,2′-azobis(4-methoxy-2,4-dimethylvaleronitrile), benzoyl peroxide, lauryl peroxide, t-butyl peroxy pivalate, 1,1-bis(t-butylperoxy)cyclohexane, p-dimethylaminoacetophenone, 2-benzyl-2-(dimethylamino)-1-[4-(4-morpholinyl)phenyl]-1-butanone, 2-hydroxy-2-methyl-1-phenyl-propan-1-one, benzyl dimethyl ketal, benzophenone, benzoin propyl ether, diethyl thioxanthone, 2,4-bis (trichloromethyl)-6-p-methoxyphenyl-s-triazine, 2-trichloromethyl-5-styryl-1,3,4-oxodiazole, 9-phenylacridine, 3-methyl-5-amino-((s-triazin-2-yl)amino)-3-phenylcoumarin, 2-(o-chlorophenyl)-4,5-diphenylimidazolyl dimer 1-phenyl-1,2-propanedione-2-(o-ethoxycarbonyl)oxime, 1-[4-(phenythio)phenyl]-octane-1,2-dione-2-(o-benzoyloxime), o-enzoyl-4′-(benzmercapto)benzoyl-hexyl-ketoxime, 2,4,6-trimethylphenycarbonyl-diphenylphosphonyloxide, a hexafluorophosphoro-trialkylphenylsulfonium salt, 2-mercaptobenzimidazole, 2,2′-benzothiazolyl disulfide, (E)-2-(4-styrylphenyl)-4,6-bis(trichloromethyl)-1,3,5-triazine, 2-dimethylamino-2-(4-methylbenzyl)-1-(4-morpholin-4-ylphenyl)-butane-1-one, and a mixture thereof, but it is not limited thereto.

For reference, examples of the commercially available oxime-based photopolymerization initiator include SPI-03 (Samyang), OXE-01 (BASF), OXE-02 (BASF), OXE-03 (BASF), N-1919 (ADEKA), NCI-930 (ADEKA) and NCI-831 (ADEKA). In addition, examples of the commercially available triazine-based photopolymerization initiator include Triazine-Y (Tronly) and Triazine-Y (Pharmasynthese).

The photopolymerization initiator may be employed in an amount of 10 to 30 parts by weight, 10 to 25 parts by weight, 10 to 20 parts by weight, or 10 to 18 parts by weight, based on 100 parts by weight of the copolymer (A) (based on the solids content).

Specifically, the oxime-based photopolymerization initiator may be employed in an amount of 1 to 20 parts by weight, 1 to 18 parts by weight, 5 to 20 parts by weight, 5 to 18 parts by weight, 8 to 20 parts by weight, or 8 to 18 parts by weight, based on 100 parts by weight of the copolymer (A) (based on the solids content). The triazine-based photopolymerization initiator may be employed in an amount of 1 to 10 parts by weight, 1 to 9 parts by weight, 1 to 8 parts by weight, 2 to 10 parts by weight, 2 to 8 parts by weight, or 3 to 6 parts by weight. The ketone-based photopolymerization initiator may be employed in an amount of 1 to 10 parts by weight, 1 to 9 parts by weight, 1 to 8 parts by weight, 2 to 10 parts by weight, 2 to 8 parts by weight, or 2 to 6 parts by weight.

If an oxime-based photopolymerization initiator is employed in an amount within the above range, the development and coating characteristics can be enhanced together with high sensitivity. In addition, if a triazine-based photopolymerization initiator is employed in an amount within the above range, a coated film with excellent chemical resistance and taper angles upon the formation of a pattern may be obtained together with high sensitivity.

### (D) Colorant

The colored photosensitive resin composition of the present invention comprises a colorant to impart the light-shielding property thereto. The colorant employed in the present invention may be a mixture of two or more inorganic or organic colorants. It preferably has high chromogenicity and high heat resistance.

The colorant comprises a black colorant and a colorant (d3) other than black.

The black colorant may be a black inorganic colorant (d2), a black organic colorant (d1), or a combination thereof. Specifically, the black colorant may comprise a black inorganic colorant and may be employed in an amount of 0.01 to 50% by weight based on the total weight of the solids content of the colored photosensitive resin composition.

Any black inorganic colorant, any black organic colorant, and any colorant other than black known in the art may be used. For example, any compounds classified as a pigment in the Color Index (published by The Society of Dyers and Colourists) and any dyes known in the art may be used.

Particular examples of the black inorganic colorant may include carbon black, titanium black, a metal oxide such as Cu—Fe—Mn-based oxide and synthetic iron black, and the like. It is preferable to use carbon black among them from the viewpoint of pattern characteristics and chemical resistance.

Particular examples of the black organic colorant may include aniline black, lactam black, perylene black, and the like. Preferred among them is lactam black (e.g., Black 582 from BASF) from the viewpoint of optical density, dielectricity, and the like.

Particular examples of the colorant other than black may include C.I. Pigment Yellow 20, 24, 31, 53, 83, 86, 93, 94, 109, 110, 117, 125, 137, 138, 139, 147, 148, 150, 153, 154, 166, 173, 180, and 185; C.I. Pigment Orange 13, 31, 36, 38, 40, 42, 43, 51, 55, 59, 61 64, 65, and 71; C.I. Pigment Red 9, 97, 105, 122, 123, 144, 149, 166, 168, 176, 177, 179, 180, 192, 215, 216, 224, 242, 254, 255, and 264; C.I. Pigment Violet 13, 14, 19, 23, 25, 27, 29, 32, 33, 36, 37, and 38; C.I. Pigment Blue 15 (15:3, 15:4, 15:6, and the like), 16, 21, 28, 60, 64, and 76; C.I. Pigment Green 7, 10, 15, 25, 36, 47, and 58; and C.I. Pigment Brown 28, Specifically, the colorant other than black may be a blue colorant, a violet colorant, or a combination thereof Preferred among them are C.I. Pigment Blue 15:6 and 60, or C.I. Pigment Violet 23, for the purpose of preventing light leakage and light blurring phenomena and from the viewpoint of dispersibility and chemical resistance of a colored dispersion composition.

The amount of the colorant may be 5 to 70% by weight, or S to 60% by weight, based on the total weight of the solids content (i.e., the weight excluding solvents) of the colored photosensitive resin composition. Specifically, the colorant may comprise 0.01 to 50% by weight of a black colorant and 0.01 to 20% by weight of a colorant other than black based on the total weight of the solids content (i.e., the weight excluding solvents) of the colored photosensitive resin composition. More specifically, the colorant comprises a black inorganic colorant or a black organic colorant and may comprise 0 to 15% by weight of a black inorganic colorant, 0 to 40% by weight of a black organic colorant, and 0.01 to 20% by weight of a colorant other than black based on the total weight of the solids content (i.e., the weight excluding solvents) of the colored photosensitive resin composition. Preferably, it may comprise 0 to 8.2% by weight of a black inorganic colorant, 0 to 45% by weight of a black organic colorant, and 0.01 to 15% by weight of a colorant other than black based on the total weight of the solids content (i.e., the weight excluding solvents) of the colored photosensitive resin composition. If the amount of the colorant is within the above range, a pattern profile upon development may be favorable, such properties as chemical resistance and elastic restoring force may be enhanced, and it is possible to achieve an optical density and a tight transmittance as desired.

A display comprising the black matrix of the present invention must have a. transmittance of 5% or less at the wavelength band of 700 nm in order to prevent the light blurring phenomenon of red or green color when a cured film is formed in a thickness of 3 pm. In addition, the transmittance in the range of 900 to 950 nm must be 10% or more in order to facilitate recognition of the alignment key in the course of placing a mask for light exposure.

Meanwhile, the colorant used in the present invention may be added to the colored photosensitive resin composition in the form of a mill base as mixed with a dispersion resin, a solvent, or the like.

The dispersion resin serves to homogeneously disperse a colorant (or a pigment) in a solvent and may be specifically at least one selected from the group consisting of a dispersant and a dispersion binder.

Examples of the dispersant may include any known dispersant for a colorant. Particular examples thereof include a cationic surfactant, an anionic surfactant, a non-ionic surfactant, a zwitterionic surfactant, a silicone-based surfactant, a fluorine-based surfactant, a polyester-based compound, a polycarboxylic acid ester-based compound, an unsaturated polyamide-based compound, a polycarboxylic acid-based compound, a polycarboxylic acid alkyl salt compound, a polyacrylic compound, a polyethyleneimine-based compound, a polyurethane-based compound, polyurethane, a polycarboxylic acid ester represented by polyacrylate, unsaturated polyamide, polycarboxylic acid, an amine salt of polycarboxylic acid, an ammonium salt of polycarboxylic acid, an alkylamine salt of polycarboxylic acid, polysiloxane, a long chain polyaminoamide phosphate salt, an ester of polycarboxylic acid whose hydroxyl group is substituted and its modified product, an amide formed by reaction of polyester having a free carboxyl group with a poly(lower alkyleneimine) or a salt thereof, a (meth)acrylic acid-styrene copolymer, a (meth)acrylic acid-(meth)acrylate ester copolymer, a styrene-maleic acid copolymer, polyvinyl alcohol, a water-soluble resin or a water-soluble polymer compound such as polyvinylpyrrolidone, modified polyacrylate, are adduct of ethylene oxide/propylene oxide, a phosphate ester, and the like. Commercially available dispersants may include Disperbyk-182, -183. -184, -185, -2000, -2150, -2155, -2163, and -2164 from BYK Co. They may be used alone or in combination of two or more thereof The dispersant may have an amine group and/or an acid group as a pigment-affinity group and may optionally be of an ammonium salt type.

The dispersant may be added in advance to a colorant through surface treatment of the colorant therewith or added together with a colorant at the time of preparing a colored photosensitive resin composition.

The amine value of the dispersant may be 5 to 200 mg KOH/g, 10 to 200 mg KOH/g, or 50 to 150 mg KOH/g. If the amine value of the dispersant is within the above range, the dispersibility and storage stability of the colorant are excellent, and the roughness of the surface of a cured film prepared from the resin composition is improved.

The dispersant may be employed in an amount of 1 to 20% by weight, or 2 to 15% by weight, based on the total weight of the colored dispersion. If the amount of the dispersant is within the above range, the colorant is effectively dispersed to improve the dispersion stability, and the optical, physical, and chemical properties are improved by virtue of maintaining an appropriate viscosity when it is applied. Thus, it is desirable in terms of an excellent balance between dispersion stability and viscosity.

If the dispersion binder has an acid value, it may comprise a monomer having a carboxyl group and an unsaturated bond. Particular examples of the monomer having a carboxyl group and an unsaturated bond include a monocarboxylic acid such as acrylic acid, methacrylic acid, and crotonic acid; a dicarboxylic acid such as fumaric acid, mesaconic acid, and itaconic acid, and an anhydride of the dicarboxylic acid; a mono(meth)acrylate of a polymer having a carboxyl group and a hydroxyl group at both terminals such as ω-carboxypolycaprolactonemono(meth)acrylates, and the like. Preferred are acrylic acid and methacrylic acid.

In addition, the dispersion binder may comprise a monomer having an unsaturated bond copolymerizable with the monomer having a carboxyl group and an unsaturated bond. Examples of the monomer having a copolymerizable unsaturated bond may, for example, include an aromatic vinyl compound such as styrene, vinyltoluene, α-methylstyrene, p-chlorostyrene o-methoxystyrene, m-methoxystyrene, p-methoxystyrene, o-vinylbenzyl methyl ether, m-vinylbenzyl methyl ether, p-vinylbenzyl methyl ether, o-vinyl benzyl glycidyl ether, m-vinyl benzyl glycidyl ether, and p-vinylbenzyl glycidyl ether; an alkyl (meth)acrylate such as methyl (meth)acrylate, ethyl (meth)acrylate, n-propyl (meth)acrylate, i-propyl (meth)acrylate, n-butyl (meth)acrylate, i-butyl (meth)acrylate, sec-butyl (meth)acrylate, and t-butyl (meth)acrylate; an alicyclic (meth)acrylates such as cyclopentyl (meth)acrylate, cyclohexyl (meth)acrylate, 2-methylcyclohexyl (meth)acrylate, tricyclo[5.2.1.0^{2,6}]decan-8-yl (meth)acrylate, 2-dicyclopentanyloxyethyl (meth)acrylate, and isobornyl (meth)acrylate; an aryl (meth)acrylate such as phenyl (meth)acrylate and benzyl (meth)acrylate; a hydroxyalkyl (meth)acrylate such as 2-hydroxyethyl (meth)acrylate and 2-hydroxypropyl (meth)acrylate; an N-substituted maleimide compound such as N-cyclohexylmaleimide, N-benzylmaleimide, N-phenylmaleimide, N-o-hydroxyphenylmaleimide, N-m-hydroxyphenylmaleimide, N-p-hydroxyphenylmaleimide, N-o-methylphenylmaleimide, N-m-methylphenylmaleimide, N-p-methylphenylmaleimide, N-o-methoxyphenylmaleimide, N-m-methoxyphenylmaleimide, and N-p-methoxyphenylmaleimide; an unsaturated amide compound such as (meth)acrylamide and N,N-dimethyl (meth)acrylamide; and an unsaturated oxetane compound such as 3-(methacryloyloxymethyl)oxetane, 3-(methacryloyloxymethyl)-3-ethyloxetane, 3-(methacryloyloxymethyl)-2-trifluoromethyloxetane, 3-(methacryloyloxymethyl)-2-phenyloxetane, 2-(methacryloyloxymethyl)oxetane, and 2-(methacryloyloxymethyl)-4-trifluoromethyloxetane, which may be used alone or in combination of two or more.

The dispersion binder may comprise 30% by mole or less of a maleimide monomer based on the total number of moles of the constituent units.

The dispersion binder may be employed in an amount of 1 to 20% by weight, or 2 to 15% by weight, based on the total weight of the colored dispersion. If the dispersion binder is employed within the above range, the resin composition can maintain an appropriate viscosity level, and it is preferable in terms of dispersion stability and developability.

The dispersion binder may be employed in an amount of 100 to 300 parts by weight, 100 to 250 parts by weight, 100 to 200 parts by weight, or 100 to 180 parts by weight, based on 100 parts by weight of the copolymer (A) (based on the solids content).

### (E) Multifunctional Thiol Compound

The colored photosensitive resin composition of the present invention may comprise a multifunctional thiol compound to increase the crosslinking efficiency at the time of curing. Specifically, the multifunctional thiol compound has high reactivity by light and heat, so that it enables the colored photosensitive resin composition to be crosslinked even at a low temperature of 100° C. or lower to form a cured film. More specifically, the functional groups of the multifunctional thiol compound react to light and heat, so that it has the crosslinking and curing by light and heat carried out properly during the curing step. In addition, it removes unreacted functional groups.

The multifunctional thiol compound may be a compound having 2 or more, 3 or more, or 4 or more mercapto groups. In the case of a compound having one mercapto group, the reactivity of the multifunctional thiol compound and the compound containing a double bond and a hydroxyl group decreases, so that the durability and adhesion may be deteriorated.

Examples of the multifunctional thiol compound having two mercapto groups include 1,3-butanedithiol, 1,4-butanedithiol, 2,3-butanedithiol, 1,2-benzenedithiol, 1,3-benzenedithiol, 1,4-benzenedithiol, 1,10-decanedithiol, 1,2-ethanedithiol, 1,6-hexanedithiol, 1,9-nonanedithiol, 1,8-octanedithiol, 1,5-pentanedithiol, 1,2-propanedithiol, 1,3-propanedithiol, toluene-3,5-dithiol, 3,6-dichloro-1,2-benzenedithiol, 1,5-naphthalenedithiol, 1,2-benzenedimethanthiol, 1,3-benzenedimethanethiol, 1,4-benzenedimethanethiol, 4,4-thiobisbenzenethiol, 2-di-n-butylamino-4,6-dimercapto-s-triazine, trimethylolpropane tris(β-thiopropion ester), 2,5-dimercapto-1,3,4-thiadiazole, 1,8-dimercapto-3,6-dioxaoctane, and 1,5-dimercapto-3-thiapentane.

Examples of the multifunctional thiol compound having three mercapto groups include thioglycerin, 1,3,5-triazine-2,4,6-trimercaptotriazine, trimethylolpropane tristhioglycolate, trimethylolpropane tristhiopropionester, 1,2,4-tris(mercaptomethyl)benzene, 1,3,5-tris(mercaptomethyl)benzene, 2,4,6-tris(mercaptomethyl)methy nitrite, tris(mercaptomethyl) isocyanurate, tris(3-mercaptopropyl) isocyanurate, 2,4,6-tris(mercaptomethyl)-1,3-dithiolane 1,3,5-triazine-2,4,6-trimercaptotriazine, tris(3-mercaptopropionyloxy)ethyl isocyanurate, and trimethylolpropanetris-3-mercaptopropionate.

Examples of the multifunctional thiol compound having four mercapto groups include pentaerythritol tetrakis thioglycolate, pentaerythritol tetrakis thiopropion ester, 1,2,4,5-tetrakis(mercaptomethyl)benzene, tetramercaptobutane, pentaerythritol tetrakis-3-mercaptopropionate, and dipentaerythritol tetrakis-3-mercaptopropionate.

Preferably, the multifunctional thiol compound may be at least one selected from the group consisting of tris(3-mercaptopropionyloxy)ethyl isocyanurate, trimethylolpropanetris-3-mercaptopropionate, pentaerythritol tetrakis-3-mercaptopropionate, and dipentaerythritol tetrakis -3-mercaptopropionate.

The multifunctional thiol compound may be employed in an amount of 10 to 50 parts by weight, 10 to 30 parts by weight, 10 to 25 parts by weight, 10 to 20 parts by weight, 15 to 25 parts by weight, or 15 to 20 parts by weight, based on 100 parts by weight of the copolymer (A) (based on the solids content).

Within the above range, the pattern profile upon development is favorable, and excellent chemical resistance and elastic restoring force may be achieved. If it is less than the above range, the post-bake is not sufficiently carried out (i.e., the curing is not completely performed). If it exceeds the above range, it is difficult to control the crosslinking efficiency because the reactivity by light and heat is excessively high, whereby defects such as detachment or protrusions on the pattern may occur during development. Further, the straightness and resolution of the pattern may also be deteriorated.

### (F) Compound Containing Two or More Double Bonds and Two or More Hydroxyl Groups

The colored photosensitive resin composition of the present invention may further comprise a compound containing a double bond and a hydroxyl group to more readily form a pattern. Specifically, the compound containing a double bond and a hydroxyl group may contain two or more double bonds and two or more hydroxyl groups.

The compound containing a double bond and a hydroxyl group may be at least one selected from the group consisting of 1,3-diglycerolate diacrylate, glycerol 1,3-diglycerolate diacrylate, ((oxybis(4,1-phenylene))bis(oxy))bis(2-hydroxypropane-3,1-diyl) diacrylate, ((propane-2,2-diylbis(4,1-phenytene))bis(oxy))bis(2-hydroxypropane-3,1-diyl) diacrylate, and (spiro[fluorene-9,9′-xanthene]-3′,6′-diylbis(oxy))bis(2-hydroxypropane-3,1-diyl) diacrylate.

In addition, it may further include a multifunctional urethane acrylate compound obtained by reacting a compound having a straight-chain alkylene group and an alicyclic structure with two or more isocyanate groups and a compound having one or more hydroxyl groups and three, four, or five acryloyloxy groups and/or methacryloyloxy groups in the molecule.

The compound containing a double bond and a hydroxyl group, as described above, enables high resolution by appropriately controlling the reactivity of the multifunctional thiol compound by heat and light during post-bake. Specifically, the hydroxyl group of the compound containing a double bond and a hydroxyl group enhances the development speed in the unexposed portion, and the hydroxyl group participates in the crosslinking reaction with the thiol group of the multifunctional thiol compound in the exposed portion, thereby enhancing the degree of curing.

The compound containing a double bond and a hydroxyl group may be employed in an amount of 10 to 50 parts by weight, 10 to 45 parts by weight, 10 to 30 parts by weight, 15 to 40 parts by weight, or 15 to 30 parts by weight, based on 100 parts by weight of the copolymer (A) (based on the solids content).

Within the above range, the pattern profile upon development is favorable, and excellent chemical resistance and elastic restoring force may be achieved. If it is less than the above range, the solubility of the composition is reduced. If it exceeds the above range, the solubility is excessive, so that the rate of decrease in pattern thickness increases during the development step, and the pattern may be detached at a high resolution of 10 μm or less.

### (G) Photobase Generator

The colored photosensitive resin composition of the present invention may comprise a photobase generator to increase the crosslinking and curing efficiency in the composition.

Specifically, the colored photosensitive resin composition of the present invention uses a photoradical polymerization initiator together with a photobase generator at the time of curing, so that the photoradical polymerization reaction and the base generation reaction from the base generator proceed simultaneously, which enhances the crosslinking efficiency in the composition.

The photobase generator is not particularly limited, but may be, for example, a photobasic compound that generates a base in response to a short wavelength or a long wavelength, or an ammonium salt having an anion and an ammonium ion having a pKa of 0 to 4.

The base generated by the photobase generator may be a secondary amine, a tertiary amine, or the like, and the base may have a boiling point of 80° C. or higher. In addition, the base may have a weight average molecular weight of 80 to 2,000 Da.

The photobase generator may be employed in an amount of 1 to 10 parts by weight, 1 to 8 parts by weight, 1 to 5 parts by weight, or 1 to 3 parts by weight, based on 100 parts by weight of the copolymer (A) (based on the solids content). Within the above range, the thermal curing and photocuring are well carried out even at a low temperature, so that a cured film having good pattern development can be formed.

### (H) Epoxy Compound

The colored photosensitive resin composition of the present invention may comprise an epoxy compound to increase the internal density of the resin, to thereby enhance the chemical resistance of a cured film formed therefrom.

The epoxy compound may be an unsaturated monomer containing at least one epoxy group, or a homo-oligomer or a hetero-oligomer thereof. Examples of the unsaturated monomer containing at least one epoxy group may include glycidyl (meth)acrylate, 4-hydroxybutylacrylate glycidyl ether, 3,4-epoxybutyl (meth)acrylate, 4,5-epoxypentyl (meth)acrylate, 5,6-epoxyhexyl (meth)acrylate, 6,7-epoxyheptyl (meth)acrylate, 2,3-epoxycyclopentyl (meth)acrylate, 3,4-epoxycyclohexyl (meth)acrylate, α-ethyl glycidyl acrylate, α-n-propyl glycidyl acrylate, α-n-butyl glycidyl acrylate, N-(4-(2,3-epoxypropoxy)-3,5-dimethylbenzyl)acrylamide, N-(4-(2,3-epoxypropoxy)-3,5-dimethylphenylpropyl)acrylamide, ally glycidyl ether, 2-methylallyl glycidyl ether, o-vinylbenzyl glycidyl ether, m-vinylbenzyl glycidyl ether, p-vinylbenzyl glycidyl ether, or a mixture thereof. Specifically, glycidyl (meth)acrylate may be used.

Examples of the commercially available homo-oligomer of an unsaturated monomer containing at least one epoxy group may include GHP-013HP (glycidyl methacrylate homopolymer, Miwon Commercial Co., Ltd.).

The epoxy compound may further comprise the following structural unit.

Particular examples thereof may include any structural unit derived from styrene; a styrene having an alkyl substituent such as methylstyrene, dimethylstyrene, trimethylstyrene, ethylstyrene, diethylstyrene, triethylstyrene, propylstyrene, butylstyrene, hexylstyrene, heptylstyrene, and octylstyrene; a styrene having a halogen such as fluorostyrene, chlorostyrene, bromostyrene, and iodostyrene; a styrene having an alkoxy substituent such as methoxystyrene, ethoxystyrene, and propoxystyrene; p-hydroxy-α-methylstyrene, acetylstyrene; an ethylenically unsaturated compound having an aromatic ring such as divinylbenzene, vinylphenol, o-vinylbenzyl methyl ether, m-vinylbenzyl methyl ether, and p-vinylbenzyl methyl ether; an unsaturated carboxylic acid ester such as methyl (meth)acrylate, ethyl (meth)acrylate, butyl (meth)acrylate, dimethylaminoethyl (meth)acrylate, isobutyl (meth)acrylate, t-butyl (meth)acrylate, cyclohexyl (meth)acrylate, ethythexyl(meth)acrylate, tetrahydrofurfuryl (meth)acrylate, hydroxyethyl (meth)acrylate, 2-hydroxypropyl (meth)acrylate, 2-hydroxy-3-chloropropy (meth)acrylate, 4-hydroxybutyl (meth)acrylate, glycerol (meth)acrylate, methyl α-hydroxymethylacrylate, ethyl α-hydroxymethylacrylate, propyl α-hydroxymethylactylate, butyl α-hydroxymethylacrylate, 2-methoxyethyl (meth)acrylate, 3-methoxybutyl (meth)acrylate, ethoxy diethylene glycol (meth)acrylate, methoxy triethylene glycol (meth)acrylate, methoxy tripropylene glycol (meth)acrylate poly(ethylene glycol) methyl ether (meth)acrylate, phenyl (meth)acrylate, benzyl (meth)acrylate, 2-phenoxyethyl (meth)acrylate, phenoxy diethylene glycol (meth)acrylate, p-nonylphenoxy polyethylene glycol (meth)acrylate, p-nonylphenoxy polypropylene glycol (meth)acrylate, tetrafluoropropyl (meth)acrylate, 1,1,1,3,3,3-hexafluoroisopropyl (meth)acrylate, octafluoropentyl (meth)acrylate, heptadecafluorodecyl (meth)acrylate, tribromophenyl (meth)acrylate, isobornyl (meth)acrylate, dicyclopentanyl (meth)acrylate, dicyclopentenyl (meth)acrylate, dicyclopentanyloxyethyl (meth)acrylate, and dicyclopentenyloxyethyl (meth)acrylate; a tertiary amine having an N-vinyl group such as N-vinyl pyrrolidone, N-vinyl carbazole, and N-vinyl morpholine; an unsaturated ether such as vinyl methyl ether and vinyl ethyl ether; an unsaturated imide such as N-phenylmaleimide, N-(4-chlorophenyl)maleimide, N-(4-hydroxyphenyl)maleimide, and N-cyclohexylmaleimide. The structural unit derived from the compounds exemplified above may be contained in the epoxy compound alone or in combination of two or more thereof.

The epoxy compound may have a weight average molecular weight of 100 to 30,000 Da. Specifically, the epoxy compound may have a weight average molecular weight of 100 to 10,000 Da. If the weight average molecular weight of the epoxy compound is 100 Da or more, the hardness of a cured film can be more excellent. If it is 30,000 Da or less, the thickness of a thin film becomes uniform with a smaller step difference, which is more suitable for planarization.

The amount of the epoxy compound may be 1 to 20 parts by weight, 1 to 10 parts by weight, 5 to 20 parts by weight, 5 to 15 parts by weight, or 5 to 10 parts by weight, based on 100 parts by weight of the copolymer (A) (based on the solids content). Within the above range, a pattern profile upon development may be favorable, such properties as chemical resistance and elastic restoring force may be enhanced, and it is possible to prevent the problem that detachment occurs in the development step or that the storage stability of the composition is deteriorated.

### (I) Adhesion Aid

The colored photosensitive resin composition according to the present invention may further comprise an adhesion aid to enhance the adhesiveness to a substrate.

The adhesion aid may have at least one reactive group selected from the group consisting of a carboxyl group, a (meth)acryloyl group, an isocyanate group, an amino group, a mercapto group, a vinyl group, and an epoxy group.

The kind of the adhesion aid is not particularly limited. It may be at least one selected from the group consisting of trimethoxysilyl benzoic acid, γ-methacryloxypropyltrimethoxysilane, vinyltriacetoxysilane, vinyltrimethoxysilane, γ-isocyanatopropyltriethoxysilane, γ-glycidoxypropyltrimethoxysilane, γ-glycidoxypropyltriethoxysilane, N-phenylaminopropyltrimethoxysilane, β-(3,4-epoxycyclohexyl)ethyltrimethoxysilane, 3-isocyanate propyltriethoxysilane, N-phenyl-3-aminopropyltrimethoxysilane, and a mixture thereof.

Preferred is γ-glycidoxypropyltrimethoxysilane, γ-glycidoxypropyltriethoxysilane, 3-isocyanate propyltriethoxysilane, N-phenyl-3-aminopropyitrimethoxysilane, or N-phenylaminopropyitrimethoxysilane, which is capable of enhancing the film retention rate and the adhesiveness to a substrate.

The amount of the adhesion aid may be 0.01 to 5 parts by weight, 0.01 to 3 parts by weight, 0.1 to 5 parts by weight, 0.1 to 3 parts by weight, 1 to 5 parts by weight, or 1 to 3 parts by weight, based on 100 parts by weight of the copolymer (A) (based on the solids content). Within the above range, the adhesiveness to a substrate may be further enhanced.

### (J) Surfactant

The colored photosensitive resin composition of the present invention may further comprise a surfactant in order to enhance the coatability and to prevent the generation of defects.

Although the kind of the surfactant is not particularly limited, for example, a. fluorine-based surfactant or silicone-based surfactant may be used. The commercially available silicone-based surfactant may include DC3PA, DC7PA, SH11PA, SH21PA, and SH8400 from Dow Corning Toray Silicone, TSF-4440, TSF-4300, TSF-4445, TSF-4446, TSF-4460, and TSF-4452 from GE Toshiba Silicone, BYK-333, BYK-307, BYK-3560, BYK UV-3535, BYK-361N, BYK-354, and BYK-399 from BYK, and the like. They may be used alone or in combination of two or more thereof.

The commercially available fluorine-based surfactant may include Megaface F-470, F-471, F-475, F-482, F-489, and F-563 from Dainippon Ink Kagaku Kogyo Co. (DIC) and F-563 from Chiba.

Preferred among these surfactants may be BYK-333 and BYK-307 from BYK and F-563 from Chiba from the viewpoint of the coatability of the composition.

The amount of the surfactant may be 0.01 to 5 parts by weight, 0.01 to 3 parts by weight, 0.1 to 5 parts by weight, or 0.1 to 3 parts by weight, based on 100 parts by weight of the copolymer (A) (based on the solids content). Within the above range, the colored photosensitive resin composition may be smoothly coated.

### (K) Solvent

The colored photosensitive resin composition of the present invention may preferably be prepared as a liquid composition in which the above components are mixed with a solvent. Any solvent known in the art, which is compatible but not reactive with the components in the colored photosensitive resin composition, may be used in the preparation of the colored photosensitive resin composition.

Examples of the solvent may include glycol ethers such as ethylene glycol monoethyl ether; ethylene glycol alkyl ether acetates such as ethyl cellosolve acetate; esters such as ethyl 2-hydroxypropionate; diethylene glycols such as diethylene glycol monomethyl ether; propylene glycol alkyl ether acetates such as propylene glycol monomethyl ether acetate and propylene glycol propyl ether acetate; and alkoxyalkyl acetates such as 3-methoxybutyl acetate. The solvent may be used alone or in combination of two or more.

The amount of the solvent is not particularly limited, but it may be 50 to 90% by weight, or 70 to 85% by weight, based on the total weight of the colored photosensitive resin composition finally prepared from the viewpoint of coatability and stability of the colored photosensitive resin composition finally obtained. If the amount of the solvent is within the above range, the resin composition is smoothly coated, and the delay margin, which may occur in the working process, is small.

In addition, the colored photosensitive resin composition of the present invention may comprise other additives such as an antioxidant and a stabilizer as long as the physical properties of the colored photosensitive resin composition are not adversely affected.

The colored photosensitive resin composition of the present invention comprising the above-described components may be prepared by a common method, for example, by the following method.

At first, a colorant is mixed with a dispersion resin, a dispersant, and a solvent in advance and dispersed therein using a bead mill until the average particle diameter of the colorant reaches a desired value, thereby preparing a colored dispersion liquid. In such event, a surfactant and/or a copolymer may be blended in part or in entirety. Added to the dispersion liquid are the remainder of the copolymer and the surfactant, a photopolymerizable compound, a photopolymerization initiator, a multifunctional thiol compound, and a compound containing a double bond and a hydroxyl group. An additive such as an epoxy compound or an additional solvent, if necessary, is further blended to a certain concentration, followed by sufficiently stirring them to obtain a colored photosensitive resin composition as desired.

The present invention also provides a light-shielding black matrix prepared from the colored photosensitive resin composition.

The black matrix may be prepared by a coating formation step, a light exposure step, a development step, and a heating step.

In the coating formation step, the colored photosensitive resin composition according to the present invention is coated on a pre-treated substrate by a spin coating method, a slit coating method, a roll coating method, a screen printing method, an applicator method, or the like in a desired thickness, for example, 1 to 25 μm, which is then pre-baked at a temperature of 70 to 100° C. for 1 to 10 minutes to form a coated film by removing the solvent therefrom.

In order to form a pattern on the coated film, a mask having a predetermined shape is placed thereon, which is then irradiated with activated rays of 200 to 500 nm. As a light source used for the irradiation, a low-pressure mercury lamp, a high-pressure mercury lamp, an extra high-pressure mercury lamp, a metal halide lamp, an argon gas laser, or the like may be used. X-ray, electronic ray, or the like may also be used, if desired. The dose of light for exposure may vary depending on the kind and the compositional ratio of the components of the composition and the thickness of a dried coating. If a high-pressure mercury lamp is used, it may be 500 mJ/cm² or less (at the wavelength of 365 nm).

After the light exposure step, an aqueous alkaline solution such as sodium carbonate, sodium hydroxide, potassium hydroxide, tetramethylammonium hydroxide, or the like as a developer is used to dissolve and remove unnecessary portions, whereby only an exposed portion remains to form a pattern. An image pattern obtained by the development is cooled to room temperature and post-baked in a hot air circulation-type drying furnace at a temperature of 50 to 100° C., 50 to 90° C., or 60 to 90° C. for 10 to 60 minutes, thereby obtaining a final pattern.

Since the light-shielding black matrix thus prepared has excellent properties, it can be advantageously used in an electronic device for liquid crystal displays and quantum dot displays. Thus, the present invention provides an electronic device comprising the light-shielding black matrix.

The liquid crystal displays and quantum dot displays may comprise other components known to those skilled in the art, except that they are provided with the black matrix of the present invention. That is, the liquid crystal displays and quantum dot displays, to which the black matrix of the present invention can be applied, may fall within the scope of the present invention.

### Embodiments for Carrying Out the Invention

Hereinafter, the present invention will be described in more detail with reference to the following examples. However, these examples are provided to illustrate the present invention, and the scope of the present invention is not limited thereto only.

In the following preparation examples, the weight average molecular weight is determined by gel permeation chromatography (GPC, eluent: tetrahydrofuran) referenced to a polystyrene standard.

### Example

### Preparation Example 1: Preparation of a Copolymer (A-1)

A 250 ml, round-bottomed flask equipped with a refluxing condenser and a stirrer in a nitrogen atmosphere was charged with a monomer mixture composed of10.68 g (32% by mole) of styrene, 8.01 g (25% by mole) of methyl methacrylate, 10.43 g (15% by mole) of 2-acryloyloxyethyl succinate, 11.32 g (18% by mole) of 2,4-epoxycyclohexylmethyl methacrylate, and 4.56 g (10% by mole) of glycidyl methacrylate, along with 2.34 g (3.0% by mole) of V-65 as a radical polymerization initiator, dissolved in 107.98 g of propylene glycol monomethyl ether acetate (PGMEA). Thereafter, polymerization was carried out at 65° C. and for 18 hours to obtain a copolymer (A-1) having a solids content of 31.32% by weight. The copolymer thus prepared had an acid value of 19.93 mg KOH/g, a polydispersity (Mw/Mn) of 4.38, and a weight average molecular weight (Mw) of 35,000 Da.

### Preparation Example 2: Preparation of a Copolymer (A-2)

A 500-ml, round-bottomed flask equipped with a refluxing condenser and a stirrer was charged with 100 g of a monomer mixture composed of 43% by mole of styrene, 27.5% by mole of methyl methacrylate, 20.5% by mole of methacrylic acid, and 9% by mole of glycidyl methacrylate, along with 300 g of propylene glycol methyl ether acetate (PGMEA) as a solvent and 3 g of 2,2′-azobis(2,4-dimethylvaleronitrile) as a radical polymerization initiator. The mixture was then heated to 70° C. and stirred for 5 hours to obtain a copolymer (A-2) having a solids content of 29.8% by weight. The copolymer thus prepared had an acid value of 28 mg KOH/g and a weight average molecular weight (Mw) of 6500 Da,

### Preparation Example 3: Preparation of a Copolymer (A-3)

A 500-ml, round-bottomed flask equipped with a refluxing condenser and a stirrer was charged with 100 g of a monomer mixture composed of 51% by mole of N-phenylmaleimide, 4% by mole of styrene, 10% by mole of 4-hydroxybutyl acrylate glycidyl ether, and 35% by mole of methacrylic acid, along with 300 g of propylene glycol methyl ether acetate (PGMEA) as a solvent and 2 g of 2,2′-azobis(2,4-dimethylvaleronitrile) as a radical polymerization initiator. The mixture was then heated to 70° C.′ and stirred for 5 hours to obtain a copolymer (A-3) having a solids content of 31.3% by weight. The copolymer thus prepared had an acid value of 31.7 mg KOH/g and a weight average molecular weight (Mw) of 20,545 Da.

### Examples and Comparative Examples: Preparation of Photosensitive Resin Compositions

The components used in the following Examples and Comparative Examples are as follows.

TABLE 2

| | | | Solids content | |
|---|---|---|---|---|
| Component | | | (% by weight) | Manufacturer |
| Copolymer (A) | | Preparation Example 1 | 31.32 | — |
| | | Preparation Example 2 | 29.8 | — |
| | | Preparation Example 3 | 31.3 | — |
| Photopolymerizable | | Dipentaerythritol hexaacrylate | 100 | Nippon Kayaku |
| compound (B) | | (DPHA) | | |
| Photopolymerization | C-1 | Oxime-based photopolymerization | 100 | Samyang |
| initiator (C) | | initiator | | |
| | C-2 | (E)-2-(4-styrylphenyl)-4,6- | 100 | Pharmasynthese |
| | | bis(trichloromethyl)-1,3,5-triazine | | |
| | | (Triazine-Y) | | |
| Colorant (D) | D-1 | Organic carbon (organic black) + | 20.1 | Tokushiki |
| | | dispersant + binder BK-7544 | | |
| | D-2 | Carbon black + dispersant + binder | 21.3 | Tokushiki |
| | | BK-7539 | | |
| | D-3 | Pigment Blue (15:6) + dispersant + | 16.97 | IRIDOS |
| | | Binder Blue B2 | | |
| Multifunctional thiol compound | | Pentaerythritol tetrakis(3- | 100 | Aldrich |
| (E) | | mercaptopropionate) (PETMP) | | |
| Compound containing a | F-1 | 1,3-diglycerolate diacrylate | 100 | Aldrich |
| double bond and an OH | F-2 | LTM II | 100 | BASF |
| group (F) | | | | |

| | | | |
|---|---|---|---|
| Photobase generator (G) | 9-anthrylmethyl N,N-ethylcarbamate | 100 | Chemtros |
| Epoxy compound (H) | Glycidyl methacrylate homopolymer | 100 | Miwon |
| | (GHP-03) | | |
| Adhesion Aid (I) | N-phenyl-3- | 100 | JNC |
| | aminopropyltrimethoxysilane | | |
| Surfactant (J) | F-563 | 100 | Chiba |
| Solvent (K) | Propylene glycol monomethyl ether | — | Chemtronix |
| | acetate (PGMEA) | | |

### Example 1

100 parts by weight of the copolymer (A-1) of Preparation Example 1, 32.143 parts by weight of dipentaerythritol hexaacrylate as a photopolymerizable compound (B), 10.944 parts by weight of an oxime-based photopolymerization initiator (C-1), 3.648 parts by weight of a triazine-based photopolymerization initiator (C-2), 112.359 parts by weight of a colorant (D-1), 16.051 parts by weight of a colorant (D-2), 32.103 parts by weight of a colorant (D-3), 19.644 parts by weight of a multifunctional thiol compound (E), 26.785 parts by weight of a compound (F-1) containing two or more double bonds and two or more hydroxyl groups, 1.824 parts by weight of a photobase generator (G), 7.296 parts by weight of an epoxy compound (H) GHP-03, 1.459 parts by weight of adhesion aid (I), and 0.547 parts by weight of F-563 as a surfactant (J) were homogeneously mixed. Here, the respective contents are those based on the solids content exclusive of solvents. The mixture was dissolved in PGMEA such that that the solids content of the mixture was 19% by weight, The resultant was mixed for 2 hours to prepare a liquid-phase photosensitive resin composition.

### Examples 2 to 4 and Comparative Examples 1 to 10

Photosensitive resin compositions were each prepared in the same manner as in Example 1, except that the kinds and/or the contents of the respective components were changed as shown in Tables 3 and 4 below.

TABLE 3

| | | | | | Photopolymerization | | | | |
|---|---|---|---|---|---|---|---|---|---|
| | Copolymer (A) | | | Photopolymerizable | initiator (C) | | Colorant (D) | | |
| | A1 | A-2 | A-3 | compound (B) | C1 | C-2 | D-1 | D-2 | D-3 |
| Ex. 1 | 100 | — | — | 32.143 | 10.944 | 3.648 | 112.359 | 16.051 | 32.103 |
| Ex. 2 | 64.286 | 35.714 | — | 32.143 | 10.515 | 3.505 | 107.949 | 15.421 | 30.843 |
| Ex. 3 | — | — | 100 | 32.143 | 10.944 | 3.648 | 112.36 | 16.051 | 32.103 |
| Ex. 4 | 100 | — | — | 32.143 | 10.944 | 3.648 | 112.359 | 16.051 | 32.103 |
| C. Ex. 1 | — | — | 100 | — | 10.515 | 3.505 | 107.949 | 15.421 | 30.843 |
| C. Ex. 2 | 100 | — | — | — | 10.515 | 3.505 | 107.949 | 15.421 | 30.843 |
| C. Ex. 3 | — | — | 100 | 78.572 | 10.515 | 3.505 | 107.949 | 15.421 | 30.843 |
| C. Ex. 4 | — | 100 | — | 78.572 | 10.514 | 3.505 | 107.949 | 15.421 | 30.843 |
| C. Ex. 5 | 100 | — | — | 58.929 | 10.515 | 3.505 | 107.949 | 15.421 | 30.843 |
| C. Ex. 6 | 100 | — | — | 39.285 | 10.515 | 3.505 | 107.949 | 15.421 | 30.843 |
| C. Ex. 7 | 100 | — | — | — | 10.515 | 3.505 | 107.949 | 15.421 | 30.843 |
| C. Ex. 8 | 100 | — | — | 67.857 | 6.809 | — | 104.862 | 14.98 | 29.961 |
| C. Ex. 9 | 100 | — | — | 39.286 | 6.809 | — | 104.862 | 14.98 | 29.961 |
| C. Ex. 10 | 100 | — | — | 78.571 | 6.809 | — | 104.862 | 14.98 | 29.961 |

TABLE 4

| | | Compound containing a | | | | | |
|---|---|---|---|---|---|---|---|
| | Multifunctional | double bond and an OH | | Photobase | Epoxy | Adhesion | |
| | thiol compound | group (F) | | generator | compound | Aid | Surfactant |
| | (E) | F-1 | F-2 | (G) | (H) | (I) | (J) |
| Ex. 1 | 19.614 | 26.785 | — | 1.821 | 7.296 | 1.159 | 0.517 |
| Ex. 2 | 19.644 | 26.785 | 26.786 | 1.752 | — | 1.402 | 0.526 |
| Ex. 3 | 19.614 | 26.785 | — | 1.821 | 7.296 | 1.159 | 0.517 |
| Ex. 4 | 19.644 | 26.785 | — | 1.824 | 7.296 | 1.159 | 0.517 |
| C. Ex. 1 | — | 78.572 | — | 1.752 | — | 1.402 | 0.526 |
| C. Ex. 2 | — | 78.572 | — | 1.752 | — | 1.402 | 0.526 |
| C. Ex. 3 | — | — | — | 1.752 | — | 1.402 | 0.526 |
| C. Ex. 4 | — | — | — | 1.752 | — | 1.402 | 0.526 |
| C. Ex. 5 | 19.644 | — | — | 1.752 | — | 1.402 | 0.526 |
| C. Ex. 6 | 39.286 | — | — | 1.752 | — | 1.402 | 0.526 |
| C. Ex. 7 | 78.571 | — | — | 1.752 | — | 1.402 | 0.526 |
| C. Ex. 8 | 10.714 | — | — | 3.405 | — | 1.362 | 0.511 |
| C. Ex. 9 | — | 39.286 | — | 3.405 | — | 1.362 | 0.511 |
| C. Ex. 10 | — | — | — | 3.105 | — | 1.362 | 0.511 |

### Preparation of Cured Films

The photosensitive resin compositions obtained in the Examples and the Comparative Examples were each coated on a glass substrate using a spin coater and pre-baked at 85° C. for 150 seconds to form a coated film in a thickness of 1.6 μm. A mask prepared to form a line pattern having a size of 5 μm by 100% exposure was placed on the coated film to have a distance of 50 μm from the substrate, which was then subjected to exposure to light. Thereafter, the coated film was irradiated with light at an exposure dose of 50 mJ/cm² based on a wavelength of 365 nm for a certain period of time using an aligner (model name: MA6), which emits light having a wavelength of 200 nm to 450 nm. Thereafter, it was developed at 24° C. with an aqueous solution of potassium hydroxide diluted to a concentration of 0.04% by weight until the unexposed portion was completely washed out. The pattern thus formed was post-baked in an oven at 85° C. for 60 minutes to obtain a cured film.

### Evaluation Example 1: Evaluation of Development Time and Detachability

A cured film having a total thickness of 1.5 (±0.1) μm upon post-bike was prepared according to the method for preparing a cured film as described above. In such event, the time for which the unexposed portion was completely washed out (until the stage O-ring part of the development apparatus was completely seen behind the substrate) with an aqueous solution of 0.04% by weight of potassium hydroxide in the process for the preparation of a cured film was measured as the development time. In addition, the degree of detachment during development was visually evaluated. The results are shown in Table 5 below.

### Development Time/Detachability

⊚: 16 seconds to 75 seconds/no defects upon visual inspection

○: greater than 75 seconds to 150 seconds/the unexposed portion detached into fine grains

x: less than 16 seconds or greater than 150 seconds/the unexposed portion detached into irregular lumps

### Evaluation Example Evaluation of Pattern Straightness And Adhesion

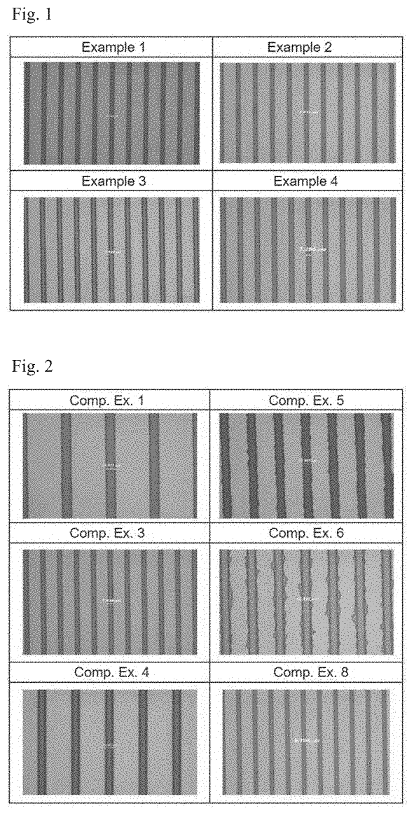

A cured film having a thickness of 1.5 (±0.1) μm prepared by the same method as in Evaluation Example 1 was measured for the thickness and critical dimension size using the SNU equipment. In addition, the degree of straightness of the line pattern formed on the cured film and whether there was any loss in the pattern was visually checked using an optical microscope. The results are shown in Table 5 below and FIGS. 1 and 2.

⊚: parallel pattern was formed without defects such as protrusions (good straightness)
○: defects such as protrusions on the pattern

x: a lot of defects such as protrusions on the pattern

### Evaluation Example 3: Evaluation of Chemical Resistance

A cured film having a thickness of 1.5 (±0.1) μm prepared by the same method as in Evaluation Example 1 was cut to a size of 2 cm×1 cm to prepare a specimen. A chemical-resistant container was charged with 10 ml of PG-MEA the cap was closed, and water bathed at 85° C. Then, the specimen was immersed and bathed for 10 minutes. The specimen was taken out after 10 minutes, cooled to room temperature, and washed with running water. The specimen was measured for the thickness before and after immersion in the solvent using the SNU equipment. The results are shown in Table 5 below.

⊚: 0: 10% or less of change in the thickness

○: greater than 10% to 20% of change in the thickness

x: greater than 20% of change in the thickness

TABLE 5

| | Develop- | De- | Straight- | | Chemical |
|---|---|---|---|---|---|
| | ability | tachment | ness | Adhesion | resistance |
| Ex. 1 | ○ | ⊚ | ⊚ | ⊚ | ⊚ |
| Ex. 2 | ⊚ | ⊚ | ⊚ | ⊚ | ⊚ |
| Ex. 3 | ⊚ | ○ | ○ | ⊚ | ⊚ |
| Ex. 4 | ○ | ⊚ | ⊚ | ⊚ | ⊚ |
| C. Ex. | ⊚ | x | x | x | ⊚ |
| 1 | | | | | |
| C. Ex. | Not | — | — | — | ⊚ |
| 2 | developed | | | | |
| C. Ex. | ⊚ | ⊚ | ⊚ | ⊚ | x |
| 3 | | | | | |
| C. Ex. | ⊚ | ⊚ | ⊚ | x | x |
| 4 | | | | | |
| C. Ex. | ○ | ⊚ | x | x | ○ |
| 5 | | | | | |
| C. Ex. | ○ | x | x | x | ⊚ |
| 6 | | | | | |
| C. Ex. | Not | — | — | — | ⊚ |
| 7 | developed | | | | |
| C. Ex. | x | x | ⊚ | ⊚ | x |
| 8 | | | | | |
| C. Ex. | Part of the film was detached during the development step. | | | | |
| 9 | | | | | |

| | |
|---|---|
| C. Ex. | Part of the film was detached during the development step. |
| 10 | |

As can be seen from the results of Table 5 and FIGS. 1 and 2, all of the cured films formed from the photosensitive resin compositions of Examples 1 to 4 had a fast development time and showed good straightness and adhesion without defects such as pattern detachment or protrusions during development. Further, they were excellent in chemical resistance. The cured films prepared in Comparative Examples 1 to 10 were not developed or the development time was too long, the patterns were detached or lost, and defects such as protrusions were observed on some of the patterns formed, Further, they were inferior to the Examples in terms of chemical resistance.

1. A photosensitive resin composition, which comprises:
(A) a copolymer;
(B) a photopolymerizable compound;
(C) a photopolymerization initiator;
(D) a colorant; and
(E) a multifunctional thiol compound.

2. The photosensitive resin composition of claim 1, which further comprises (F) a compound containing two or more double bonds and two or more hydroxyl groups.

3. The photosensitive resin composition of claim 1, wherein the multifunctional thiol compound (E) is at least one selected from the group consisting of tris-(3-mercaptopropionyloxy)ethyl isocyanurate, trimethylolpropanetris-3-mercaptopropionate, pentaerythritol tetrakis-3-mercaptopropionate, and dipentaerythritol tetrakis-3-mercaptopropionate. 4, The photosensitive resin composition of claim 1, which comprises the multifunctional thiol compound (E) in an amount of 10 to 50 parts by weight based on 100 parts by weight of the copolymer (A) on the basis of the solids content.

5. The photosensitive resin composition of claim 2, wherein the compound containing two or more double bonds and two or more hydroxyl groups (F) is at least one selected from the group consisting of 1,3-diglycerolate diacrylate, glycerol 1,3-diglycerolate diacrylate, ((oxybis(4,1-phenylene))bis(oxy))bis(2-hydroxy propane-3,1-diyl) diacrylate, ((propane-2,2-diylbis(4,1-phenylene))bis(oxy))bis(2-hydroxypropane-3,1-diyl) diacrylate, and (spiro[fluorene-9,9′-xanthene]-3′,6′-diylbis(oxy))bis(2-hydroxypropane-3,1-diyl) diacrylate.

6. The photosensitive resin composition of claim 1, which comprises the compound (F) in an amount of 10 to 50 parts by weight based on 100 parts by weight of the copolymer (A) on the basis of the solids content.

7. The photosensitive resin composition of claim 1, wherein the copolymer (A) comprises at least one selected from the group consisting of (a1) a structural unit derived from an unsaturated monomer containing an acid group; (a2) a structural unit derived from an unsaturated monomer containing an alicyclic epoxy group; (a3) a structural unit derived from an unsaturated monomer containing an acyclic epoxy group; and (a4) a structural unit derived from an unsaturated monomer different from (a1) to (a3).

8. The photosensitive resin composition of claim 7, wherein the unsaturated monomer containing an acid group is a succinate-based acrylate compound.

9. The photosensitive resin composition of claim 8, wherein the succinate-based acrylate compound is at least one selected from the group consisting of mono-2-acryloyloxyethyl succinate, mono-2-methacryloyloxyethyl succinate, 4-(2-(acryloxy)ethoxy)-4-oxobutanoic acid, 4-(3-(methacryloyloxy)propoxy)-4-oxobutanoic acid, and 4-((5-(methacryloyloxy)pentyl)oxy)-4-oxobutanoic acid.

10. The photosensitive resin composition of claim 7, wherein the total content of the structural units (a2) and (a3) ranges from 10% by mole to 50% by mole based on the total number of moles of the structural units of the copolymer (A).

11. The photosensitive resin composition of claim 7, wherein the molar ratio of the structural units (a2) and (a3) is 50 to 99:50 to 1.

12. The photosensitive resin composition of claim 1, wherein the colorant (D) comprises a black colorant, and the black colorant is a black inorganic colorant (d2), a black organic colorant (d1), or a combination thereof.

13. The photosensitive resin composition of claim 12, wherein the colorant (D) comprises a colorant other than black (d3), and the colorant other than black (d3) is a blue colorant, a violet colorant, or a combination thereof.

14. The photosensitive resin composition of claim 1, which further comprises a photobase generator (G).

15. A black matrix prepared from the photosensitive resin composition of claim 1.
